(19) United States
(12) Patent Application Publication
(10) Pub. No.: US 2018/0077821 A1
(43) Pub. Date: Mar. 15, 2018

(54) Energy Conversion Apparatus and Method for Generating Electric Energy from Waste Heat Source

(71) Applicant: HCL Technologies Limited, Noida (IN)

(72) Inventor: Sabarigiridharan Rajendran, Chennai (IN)

(21) Appl. No.: 15/700,459

(22) Filed: Sep. 11, 2017

(30) Foreign Application Priority Data
Sep. 12, 2016 (IN) 201611031124

(51) Int. Cl. H05K 7/20; H05K 7/14

(52) U.S. Cl. CPC H05K 7/20727; F05B 2240/93; H05K 7/1492; H05K 7/20836

(57) ABSTRACT

Disclosed is an apparatus for generating electric energy from hot air dissipated by a system. The apparatus may comprise two chambers, a set of tubular arrangements, and an outlet port. The two chambers may comprise a first chamber and a second chamber. In one embodiment, the first chamber and the second chamber may comprise a first electrode and a second electrode respectively. The set of tubular arrangements may be mounted over the first electrode and the second electrode in a manner such that the hot air may be passed through a first end towards a second end of each tubular arrangement. The passing of the hot air may enable each tubular arrangement to contract in a manner such that second end of each tubular arrangement establishes a contact with the second electrode thereby completing an electric circuit to generate the electric energy.

### CROSS-REFERENCE TO RELATED APPLICATIONS AND PRIORITY

This patent application claims priority from Indian Patent Application No. 201611031124 filed on 12 Sep. 2016, the entirety of which is hereby incorporated by reference.

### TECHNICAL FIELD

The present subject matter described herein, in general, relates to generate electric energy. More specifically an energy conversion apparatus and a method for generating electric energy from waste heat source dissipated by at least one system.

### BACKGROUND

In most of the commonly used products in sectors like Telecom or Information Technology, utilization of input power that is supplied to an electronic system is up to a maximum of 80%. It may be noted that the utilization of the input power, at times, may get reduced to 60% and remaining 20% is lost as hot air. This hot air generated is mostly unwanted and may disrupt or damage the system, if left unattended within the system. In order to keep the unwanted hot air out of the system, some of the possible means like heat exchanger such as exhaust fans may be utilized in order to dissipate and transfer the hot air out of the system. As a result, it is possible that 20% to 40% of the hot air is left as waste and liberated out of the system without reusing it. Thus, at present, waste heat energy in the form of the hot air is blown out of the electronic system and no effort has been made to conserve it. This lost hot air if properly captured may be reused for creating renewable sources of energy in an economical and eco-friendly manner.

### SUMMARY

Before the present apparatuses and methods, are described, it is to be understood that this application is not limited to the particular systems, and methodologies described, as there can be multiple possible embodiments which are not expressly illustrated in the present disclosure. It is also to be understood that the terminology used in the description is for the purpose of describing the particular versions or embodiments only, and is not intended to limit the scope of the present application. This summary is provided to introduce concepts related to systems and methods for generating electric energy from hot air dissipated by at least one system and the concepts are further described below in the detailed description. This summary is not intended to identify essential features of the claimed subject matter nor is it intended for use in determining or limiting the scope of the claimed subject matter.

In one implementation, an energy conversion apparatus for generating electric energy from hot air dissipated by at least one system is disclosed. The energy conversion apparatus may comprise at least two chambers, a set of tubular arrangements, and an outlet port. The at least two chambers may capture hot air dissipated by at least one system. The at least two chambers may further comprise a first chamber and a second chamber. In one aspect, the first chamber and the second chamber may be separated by a separating unit. In one embodiment, the first chamber and the second chamber may comprise a first electrode and a second electrode respectively. The set of tubular arrangements may be mounted over the first electrode and the second electrode. In one aspect, each tubular arrangement may comprise a first end and a second end connected to the first electrode and the second electrode respectively. In one embodiment, the tubular arrangement may be arranged in a manner such that the hot air may be passed through the first end towards the second end. The outlet port, connected with the second electrode, to dissipate the hot air passed through each tubular arrangement. In one aspect, the passing of the hot air may enable each tubular arrangement to contract in a manner such that second end of each tubular arrangement establishes a contact with the second electrode thereby completing an electric circuit to generate the electric energy.

In another implementation, a method for generating electric energy from hot air dissipated by at least one system is disclosed. In order to generate the electric energy, initially, hot air dissipated by at least one system may be captured by an energy conversion apparatus. In one aspect, the energy conversion apparatus may comprise at least two chambers comprising a first chamber and a second chamber. In one aspect, the first chamber and the second chamber may be separated by a separating unit. The first chamber and the second chamber may further comprise a first electrode and a second electrode respectively. Upon capturing the hot air, the hot air may be passed through a first end towards a second end of each tubular arrangement, of a set of tubular arrangements, mounted over the first electrode and the second electrode. In one aspect, the first end and the second end may be connected to the first electrode and the second electrode respectively. Subsequent to the passing of the hot air, each tubular arrangement may be enabled to contract in a manner such that second end of each tubular arrangement establishes a contact with the second electrode when the hot air through each tubular arrangement. After contraction of each tubular arrangement, an electric circuit may be completed to generate the electric energy from the hot air dissipated by the at least one system.

### BRIEF DESCRIPTION OF THE DRAWINGS

The foregoing detailed description of embodiments is better understood when read in conjunction with the appended drawings. For the purpose of illustrating the disclosure, example constructions of the disclosure is shown in the present document; however, the disclosure is not limited to the specific methods and apparatus disclosed in the document and the drawings.

The detailed description is given with reference to the accompanying figures. In the figures, the left-most digit(s) of a reference number identifies the figure in which the reference number first appears. The same numbers are used throughout the drawings to refer like features and components.

FIG. 1 illustrates an implementation of an energy conversion apparatus for generating electric energy from hot air dissipated by at least one system, in accordance with an embodiment of the present subject matter.

FIGS. 2A and 2B illustrate various components of the energy conversion apparatus, in accordance with an embodiment of the present subject matter.

FIGS. 3, 4A, and 4B illustrate various embodiments of implementing the energy conversion apparatus.

FIG. 5 illustrates a method for generating electric energy from hot air dissipated by at least one system, in accordance with an embodiment of the present subject matter.

### DETAILED DESCRIPTION

Some embodiments of this disclosure, illustrating all its features, will now be discussed in detail. The words “comprising,” “having,” “containing,” and “including,” and other forms thereof, are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise. Although any systems and methods similar or equivalent to those described herein can be used in the practice or testing of embodiments of the present disclosure, the exemplary, systems and methods are now described. The disclosed embodiments are merely exemplary of the disclosure, which may be embodied in various forms.

Various modifications to the embodiment will be readily apparent to those skilled in the art and the generic principles herein may be applied to other embodiments. However, one of ordinary skill in the art will readily recognize that the present disclosure is not intended to be limited to the embodiments illustrated, but is to be accorded the widest scope consistent with the principles and features described herein.

The present invention facilitates to overcome the challenges that have observed in the existing art. As it may be observed that, in telecom and/or Information Technology (IT) sectors, various electronic systems deployed tend to dissipate a lot of hot air. If not utilized, this hot air may be left as waste heat. The present invention facilitates to utilize the hot air dissipated from any electronic system(s) in order to generate electric energy. Examples of the electronic system(s) may include, but not limited to, Servers, Computing Devices, and Workstations.

In order to generate the electric energy from the hot air, initially, hot air may be captured by an energy conversion apparatus. In one aspect, the energy conversion apparatus captures the hot air by means of a fan assembly coupled with the energy conversion apparatus. The fan assembly draws the waste hot air from the electronic systems and further directs the waste hot air towards the energy conversion apparatus. In one aspect, the energy conversion apparatus may comprise at least two chambers comprising a first chamber and a second chamber. The first chamber and the second chamber may be separated by a separating unit. In one embodiment, the first chamber and the second chamber may comprise a first electrode and a second electrode respectively.

Upon capturing, the hot air may be passed through a first end towards a second end of each tubular arrangement, of a set of tubular arrangements, mounted over the first electrode and the second electrode. Subsequently, each tubular arrangement may be contract in a manner such that second ends of each tubular arrangement establish a contact with the second electrode when the hot air through each tubular arrangement. The contraction of each tubular arrangement enables to complete an electric circuit thereby generating the electric energy from the hot air dissipated by at least one system.

While aspects of described system and method for generating electric energy from hot air dissipated by at least one system and may be implemented in any number of different computing systems, environments, and/or configurations, the embodiments are described in the context of the following exemplary system.

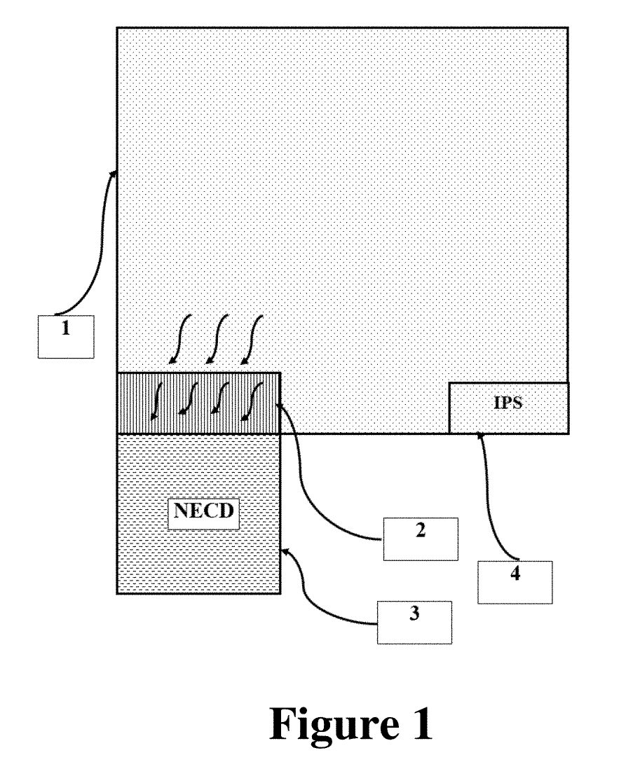

Referring now to FIG. 1, an implementation 100 of an energy conversion apparatus 3 for generating electric energy from hot air dissipated by at least one system 1 is disclosed. As illustrated in the FIG. 1, the at least one system 1 utilizes the electric energy as input received through an input power supply port 4 and generates hot air which is then dissipated and transferred out from the at least one system 1. For example, a server having one or more processors utilizes the electric energy. As the server is in continuously in operation for longs hours, the server generates heat energy in the form of hot air due to continuously running of the one or more processors. The hot air thus generated may be dissipated out from the server in order to keep the temperature, within the server, less than a predefined threshold temperature. In one aspect, the hot air generated may be dissipated out from the at least one system 1 by a fan assembly 2. It may be understood that the fan assembly 2, connected with the at least one system 1, dissipates the hot air towards the energy conversion apparatus 3 via an opening port. Once the hot air is dissipated, the energy conversion apparatus 3 captures the hot air for generating the electric energy.

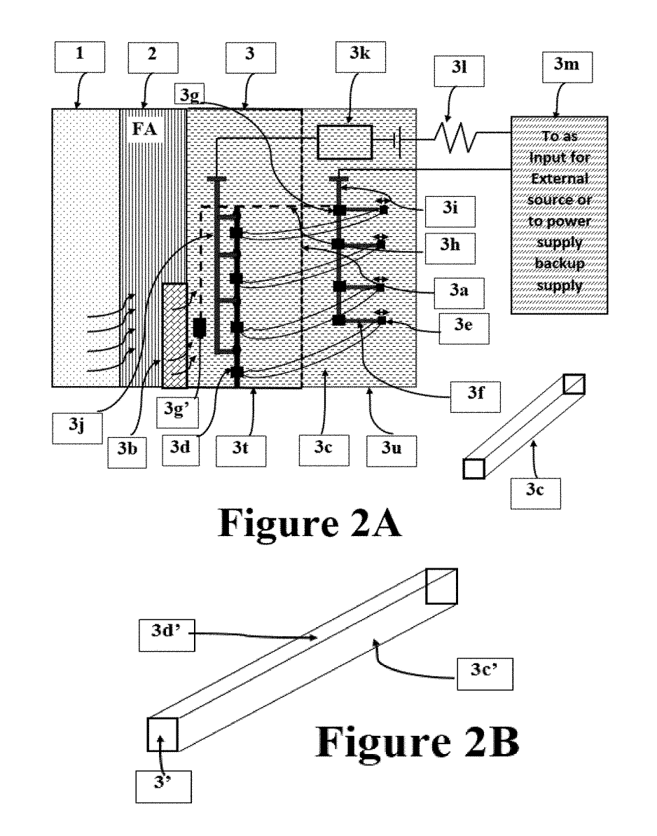

Now referring to FIG. 2A illustrating various components of the energy conversion apparatus 3, hereinafter also referred to as a New Energy Conversion Device (NECD) 3, in accordance with an embodiment of the present subject matter. In one aspect, the NECD 3 captures the hot air dissipated from the at least one system 1 by the fan assembly 2. The fan assembly 2 forcibly drives out the hot air from the at least one system 1 towards the NECD 3 through an opening port 3b. In one aspect, it is not necessary that the NECD 3 may have the fan assembly 2 but may have some thermal ways to dissipate the hot air so that fan assembly 2 may be eliminated.

In one embodiment, the NECD 3 comprises at least two chambers a first chamber 3t and a second chamber 3u. The first chamber 3t and the second chamber 3u may be separated by a separating unit 3a. In one aspect, the separating unit 3a is one of a plate and a diaphragm. In one embodiment, the plate is a simple construction as a wall to prevent leakage from the first chamber 3t to the second chamber 3u. It may be understood that the plate may be made up of a metal or a plastic. The diaphragm, on the other hand, is a thin sheet of a material forming the partition between the first chamber 3t and the second chamber 3u. The first chamber 3t and the second chamber 3u may further comprise a first electrode 3j and a second electrode 3i respectively.

The NECD 3 further comprises a set of tubular arrangements. It may be understood that the set of tubular arrangements may be made of a bimetal 3c′ at either sides of variable thermal conductivity connected by suitable metal 3d′. The suitable material facilitates support for the two bimetallic strips or plates 3c′ as shown in FIG. 2B. In one example, the bimetal may be a combination of steel and copper or steel and brass. In one embodiment, one way of tubular arrangement is shown in the FIG. 2B arrangement where 3c′ is a bimetal and 3d′ is not a bimetal (or vice versa) but facilitates the bimetal movement and supports the bimetal such that these together make the tubular arrangement as an integral unit.

As illustrated in the FIG. 2A, each tubular arrangement 3c may be mounted over the first electrode 3j and the second electrode 3i. It may be understood that each tubular arrangement 3c may comprises a first end 3d and a second end 3e connected to the first electrode 3j and the second electrode 3i respectively. In one aspect, the first end 3d is a stationery end whereas the second end 3e is a moveable end. It may be noted that the first electrode 3j arrangement (+/−) is made at the first chamber 3t and the second electrode 3i arrangement of opposite potential 3i (−/+) is made at the second chamber 3u.

In one embodiment, the second end 3e (i.e. the movable end) may further be connected to an outlet port 3g, connected with the second electrode 3i, by a rack kind of arrangement 3f. It may be understood that such kind of arrangement may be made like a parallel and/or series arrangement depending upon requirement and may further be increased for raising the energy saving potential. In one aspect, the outlet port 3g at the second chamber 3u may be connected to an inlet port 3g′ deployed at the first chamber 3t in order to reuse any heat left in the circulated air or this can be let out of system if necessary.

In addition to the above, the NECD 3 further comprises a capacitor 3k and a resistor 3l. In one aspect, the first electrode 3j and the second electrode 3i may establish a contact with the capacitor 3k and the resistor 3l in order to complete the electric circuit for generating the electric energy. The electric energy thus generated may be stored in an external power storing unit 3m that supplies the power as and when required. It may be understood that the various components, as illustrated in the FIG. 2A, and their respective arrangements facilitates the NECD 3 to generate the electric energy from the hot air dissipated by at least one system 1. The detailed functioning of each component that facilitates the NECD 3 to generate the electric energy is described below.

In order to generate the electric energy, initially, the NECD 3 captures the hot air dissipated by the at least one system 1. It may be understood that the hot air may be directed towards the NECD 3 by the fan assembly 2. Upon capturing the hot air, the hot air may be passed through each tubular arrangement 3c. This is because the set of tubular arrangements is mounted in a manner such that the hot air captured may be passed through each tubular arrangement 3c via the first end 3d towards the second end 3e. Since no escape of the hot air is allowed from each tubular arrangement 3c when entered from the first end 3d, each tubular arrangement 3c may bend and/or contract due the heat and variable conductivity of the bimetal. In one embodiment, each tubular arrangement 3c may bend or contracted in a manner such that each tubular arrangement 3c may slide on the rack 3f in a horizontal direction towards the outlet port 3g. In another embodiment, the set of tubular arrangements are mounted in a manner such that each tubular arrangement 3c may slide on the rack 3f in a vertical direction towards the outlet port.

Upon contraction each tubular arrangement 3c, when the second end 3e touches the outlet port 3g, a contact is being established with the second electrode 3i and the electric circuit (due to a presence of the capacitor 3k and the resistor 3l) is closed and thereby electric energy is being generated. In one aspect, the electric energy generated may be passed to the external power storing unit 3m. In one embodiment, when the second end 3e touches the outlet port 3g, the outlet port 3g opens and the hot air escapes out to next end or to another tubular arrangement 3c. In one embodiment, various arrangements may be made where in the hot air from outlet port 3g of a first tubular arrangement end may be passed to an inlet port of a second tubular arrangement, wherein the first tubular arrangement and the second tubular arrangement is a part of the set of tubular arrangements. It may be understood that by increasing a count of tubular arrangements, current generating potential may be increased. Thus, in this manner, the energy conversion apparatus 2 may facilitate to generate the electric energy from the hot air dissipated by at least one system 1.

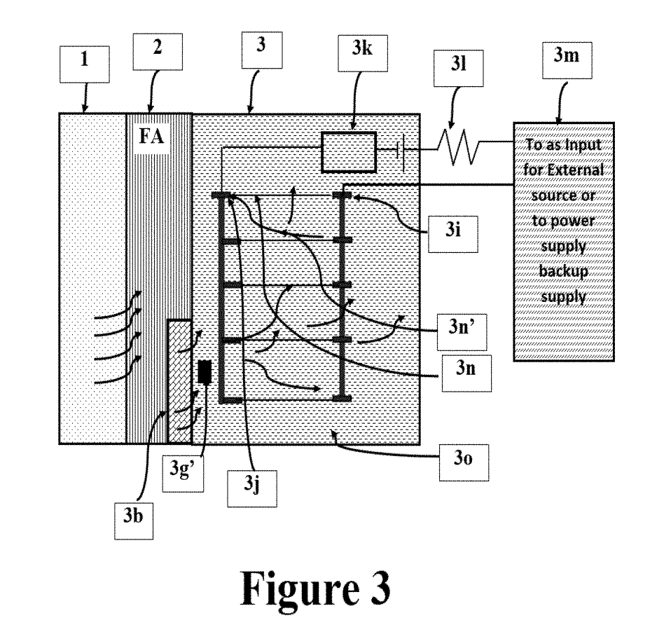

It may be understood that the aforementioned methodology for generating the electric energy using the aforementioned components of the NECD 3 may be implemented in a variety of ways. Some of the ways for implementing the NECD 3 are described below. As shown in FIG. 3, the NECD 3 is with a bimetal arrangement where the bimetal arrangement is shown in open position 3n′ and closed position 3n. In one embodiment, apart from the hot air, the NECD 3 may be filled with suitable gas 3o which may be ionized so that the excited gas particles gets attracted towards hot junction of bimetal 3n′ by which hot junction moves and forms the electric circuit in the closed position 3n and thereby generates the electric energy. It may be understood that the electric energy generated may be controlled by the capacitor 3k and the resistor 3l and stored in the external power storing unit 3m.

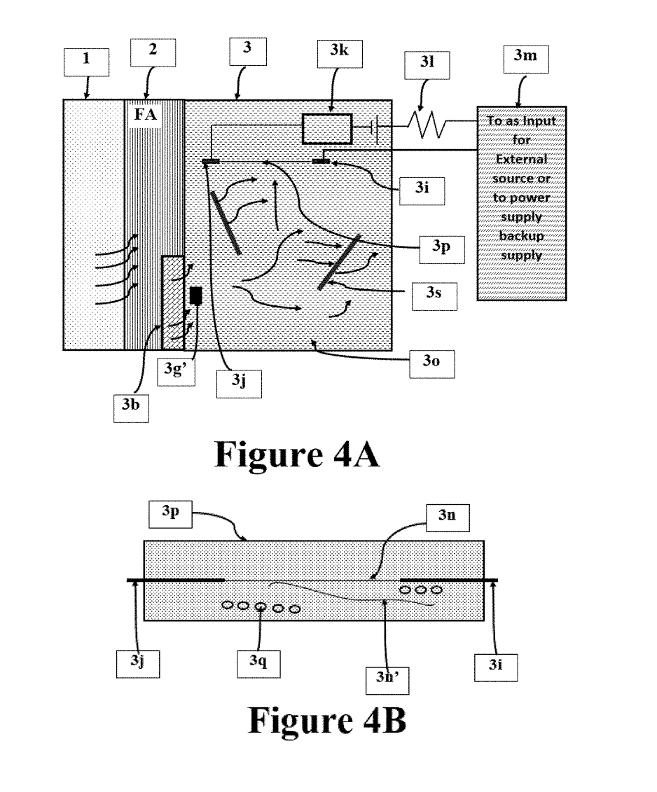

In another embodiment, the said NECD unit (3), as shown in FIG. 4A, may be a modified arrangement as explained in the FIG. 3. In this arrangement the first electrode 3j and the second electrode 3i are placed with electrolysis arrangement 3p as shown in FIG. 4B. In one aspect, a deflector 3s may be used to direct the hot air on to the electrolysis arrangement 3p in order to increase effect of the electrolysis. It may be understood that the arrangement 3p may also have dielectrics 3q to increase the effect of the electrolysis. In one aspect, when the hot air is supplied by the fan assembly 2 into the NECD 3 via the port 3b, the hot air is utilized to cause electrolysis in order to generate the electric energy which is then stored in the external power storing unit 3m.

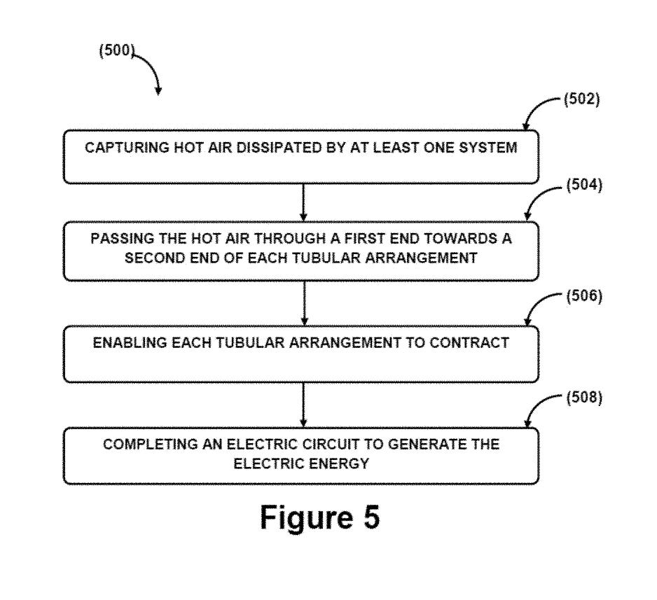

Referring now to FIG. 5, a method 500 for generating electric energy from heat energy dissipated by at least one system is shown, in accordance with an embodiment of the present subject matter. The order in which the method 500 is described is not intended to be construed as a limitation, and any number of the described method blocks can be combined in any order to implement the method 500 or alternate methods. Additionally, individual blocks may be deleted from the method 500 without departing from the spirit and scope of the subject matter described herein. Furthermore, the method can be implemented in any suitable hardware component. However, for ease of explanation, in the embodiments described below, the method 500 may be considered to be implemented as described in the energy conversion apparatus 3.

At block 502, capturing hot air dissipated by at least one system 1. In one implementation, the hot air dissipated by at least one system 1 may be captured by the energy conversion apparatus 3. In one aspect, the energy conversion apparatus 3 may comprise at least two chambers comprising a first chamber 3t and a second chamber 3u. The first chamber 3t and the second chamber 3u may be separated by a separating unit 3a. In one aspect, the first chamber 3t and the second chamber 3u may comprise a first electrode 3j and a second electrode 3i respectively

At block 504, the hot air may be passed through a first end 3d towards a second end 3e of each tubular arrangement 3c, of a set of tubular arrangements, mounted over the first electrode 3j and the second electrode 3i. In one implementation, the hot air may be passed by the energy conversion apparatus 3.

At block 506, each tubular arrangement 3c may be enabled to contract in a manner such that second end 3e of each tubular arrangement 3c establishes a contact with the second electrode 3i when the hot air is through each tubular arrangement 3c.

At block 508, an electric circuit may be completed to generate the electric energy from the hot air dissipated by at least one system 1.

Exemplary embodiments discussed above may provide certain advantages. Though not required to practice aspects of the disclosure, these advantages may include those provided by the following features.

Some embodiments enable an apparatus and a method for generating electric energy from waste heat dissipated out into the atmosphere by at least one electronic system. For example, telecom and power generation domain and technology where fan is used to drive out heat of system in most areas due to heat generating chips and devices.

Some embodiments enable an apparatus and a method for generating the electric energy more economically and eco-friendly manner

Although implementations for methods and apparatuses for generating electric energy from hot air dissipated by at least one system have been described in language specific to structural features and/or methods, it is to be understood that the appended claims are not necessarily limited to the specific features or methods described. Rather, the specific features and methods are disclosed as examples of implementations for generating the electric energy from the hot air.

We claim:

1. An energy conversion apparatus for generating electric energy from hot air dissipated by at least one system, the energy conversion apparatus comprising:
at least two chambers for capturing hot air dissipated by at least one system, the at least two chambers comprising a first chamber and a second chamber, wherein the first chamber and the second chamber is separated by a separating unit, and wherein the first chamber and the second chamber comprise a first electrode and a second electrode respectively;
a set of tubular arrangements mounted over the first electrode and the second electrode, wherein each tubular arrangement comprises a first end and a second end connected to the first electrode and the second electrode respectively, and wherein the tubular arrangement is arranged in a manner such that the hot air is passed through the first end towards the second end; and
an outlet port, connected with the second electrode, to dissipate the hot air passed through each tubular arrangement, wherein the passing of the hot air enables each tubular arrangement to contract in a manner such that second end of each tubular arrangement establishes a contact with the second electrode thereby completing an electric circuit to generate the electric energy.

2. The energy conversion apparatus of claim 1, wherein the separating unit is one of a plate and a diaphragm.

3. The energy conversion apparatus of claim 1, wherein a tubular arrangement of the set of tubular arrangements is made of a bimetal.

4. The energy conversion apparatus of claim 1 further comprises an inlet port deployed at the first chamber, wherein the inlet port facilitates to reutilize the hot air dissipated from the at least system or from second end of each tubular arrangement.

5. The energy conversion apparatus of claim 1 further comprises a capacitor, a resistor, and an external power storing unit, wherein the capacitor and the resistor are connected with the first electrode and the second electrode to complete the electric circuit for generating the electric energy and thereby storing the electric energy in the external power storing unit.

6. The energy conversion apparatus of claim 1 further comprises a fan assembly, coupled with the energy conversion apparatus for directing the hot air dissipated by at least one system towards the energy conversion apparatus.

7. The energy conversion apparatus of claim 1, wherein the first end is a stationery end and the second end is a moveable end.

8. A method for generating electric energy from hot air dissipated by at least one system, the method comprising:
capturing, by an energy conversion apparatus, hot air dissipated by at least one system, wherein the energy conversion apparatus comprises at least two chambers comprising a first chamber and a second chamber, wherein the first chamber and the second chamber is separated by a separating unit, and wherein the first chamber and the second chamber comprises a first electrode and a second electrode respectively;
passing, by the energy conversion apparatus, the hot air through a first end towards a second end of each tubular arrangement, of a set of tubular arrangements, mounted over the first electrode and the second electrode, wherein the first end and the second end are connected to the first electrode and the second electrode respectively;
enabling each tubular arrangement to contract in a manner such that second end of each tubular arrangement establishes a contact with the second electrode when the hot air through each tubular arrangement; and
completing an electric circuit to generate the electric energy from the hot air dissipated by at least one system.

9. The method of claim 8 further comprises dissipating the hot air passed through each tubular arrangement via an outlet port connected with the second electrode.

10. The method of claim 8 further comprises enabling, by an inlet port deployed at the first chamber, reutilization of the hot air dissipated from the at least system or from second end of each tubular arrangement.

11. The method of claim 8, wherein the electricity is generated by completing the electric circuit using a capacitor and a resistor.

12. The method of claim 8, wherein the first end is a stationery end and the second end is a moveable end.
